(19) United States
(12) Patent Application Publication
(10) Pub. No.: US 2016/0027854 A1
(43) Pub. Date: Jan. 28, 2016

(54) THIN FILM TRANSISTOR AND DISPLAY DEVICE INCLUDING THE SAME

(71) Applicant: SAMSUNG DISPLAY CO., LTD., Yongin-City (KR)

(72) Inventor: Suk Hoon Ku, Yongin-City (KR)

(21) Appl. No.: 14/709,411

(22) Filed: May 11, 2015

(30) Foreign Application Priority Data
Jul. 25, 2014 (KR) 10-2014-0094797

(51) Int. Cl. H01L 27/32; H01L 29/786

(52) U.S. Cl. CPC H01L 27/3262; H01L 29/78603; H01L 29/78666; H01L 29/78675; H01L 29/7869; H01L 29/78606

(57) ABSTRACT

A thin film transistor includes: a semiconductor layer on a base substrate, and having a source region, a drain region, and a channel region; a gate insulating layer covering the semiconductor layer; a gate electrode on the gate insulating layer and overlapping the channel region; an interlayer insulating layer covering the gate electrode; a source electrode and a drain electrode on the interlayer insulating layer and respectively coupled to the source region and the drain region; and a temperature adjusting member configured to adjust a temperature of the channel region by heating the channel region.

### CROSS-REFERENCE TO RELATED APPLICATION

This application claims priority to and the benefit of Korean Patent Application No. 10-2014-0094797, filed on Jul. 25, 2014, in the Korean Intellectual Property Office, the contents of which are incorporated herein by reference in their entirety.

### BACKGROUND

1. Field

Embodiments of the present invention relate to a thin film transistor, and a display device including the same, and more particularly, to a thin film transistor with improved reliability and a display device including the same.

2. Description of the Related Art

An active-matrix display device uses a thin film transistor as a switching device or a driving device. The thin film transistor controls a current flow between its source electrode and drain electrode according to a voltage applied to its gate electrode. In order to apply the thin film transistor to the active-matrix display device, a current flow property of thin film transistors should be uniform.

Lack of uniformity of the current flow characteristic may be generated by hysteresis of the thin film transistor. The hysteresis is a phenomenon in which an amount of a current between the source electrode and the drain electrode is not only determined by an intensity of a voltage applied to the gate electrode, but is also dependent on a process of a change in a state of the thin film transistor.

When the hysteresis increases, reliability of the thin film transistor deteriorates. Accordingly, when using thin film transistors in an active-matrix display device, it is desirable to reduce the hysteresis of the thin film transistors.

### SUMMARY

Embodiments of the present invention may reduce the above-described problems, and provide thin film transistors with improved reliability and a display device including the thin film transistors with improved reliability.

An exemplary embodiment of the present invention provides a thin film transistor, including: a semiconductor layer on a base substrate and having a source region, a drain region, and a channel region; a gate insulating layer covering the semiconductor layer; a gate electrode on the gate insulating layer and overlapping the channel region; an interlayer insulating layer covering the gate electrode; a source electrode and a drain electrode on the interlayer insulating layer and respectively coupled to the source region and the drain region; and a temperature adjusting member configured to adjust a temperature of the channel region by heating the channel region.

The thin film transistor may further include a buffer layer between the base substrate and the semiconductor layer. The buffer layer may include: a first buffer layer on the base substrate; and a second buffer layer on the first buffer layer.

The temperature adjusting member may be between the first buffer layer and the second buffer layer, and overlap the semiconductor layer.

A width of the temperature adjusting member in a direction perpendicular to a current flow of the temperature adjusting member may be larger than a length of the channel region.

The interlayer insulating layer may include: a first interlayer insulating layer configured to cover the gate electrode; and a second interlayer insulating layer on the first interlayer insulating layer. Herein, the temperature adjusting member may be between the first interlayer insulating layer and the second interlayer insulating layer, and overlap the gate electrode.

A width of the temperature adjusting member in a direction perpendicular to a current flow of the temperature adjusting member may be smaller than a width of the gate electrode.

The temperature adjusting member may be spaced apart from the source electrode at a side of the source electrode.

The temperature adjusting member may include at least one of amorphous silicon, polycrystalline silicon, aluminum, an aluminum alloy, titanium, and a titanium alloy.

Another exemplary embodiment of the present invention provides a display device including: a base substrate; a thin film transistor on the base substrate; a light emitting device coupled with the thin film transistor; and a temperature adjusting member insulated from the thin film transistor and configured to adjust a temperature of the thin film transistor by heating the thin film transistor.

The thin film transistor may include a semiconductor layer on the base substrate and having a source region, a drain region, and a channel region; a gate insulating layer covering the semiconductor layer; a gate electrode on the gate insulating layer and overlapping the channel region; an interlayer insulating layer covering the gate electrode; and a source electrode and a drain electrode on the interlayer insulating layer and respectively coupled to the source region and the drain region.

The display device may further comprise a buffer layer between the base substrate and the thin film transistor, wherein the buffer layer includes: a first buffer layer on the base substrate; and a second buffer layer on the first buffer layer.

The temperature adjusting member may be between the first buffer layer and the second buffer layer, and overlap the semiconductor layer.

A width of the temperature adjusting member in a direction perpendicular to a current flow of the temperature adjusting member may be larger than a length of the channel region.

The interlayer insulating layer may include a first interlayer insulating layer covering the gate electrode; and a second interlayer insulating layer on the first interlayer insulating layer, wherein the temperature adjusting member is between the first interlayer insulating layer and the second interlayer insulating layer, and overlaps the gate electrode.

A width of the temperature adjusting member in a direction perpendicular to a current flow of the temperature adjusting member may be smaller than a width of the gate electrode.

The temperature adjusting member may be spaced apart from the thin film transistor at a side of the thin film transistor.

The temperature adjusting member may include at least one of amorphous silicon, polycrystalline silicon, aluminum, an aluminum alloy, titanium, and a titanium alloy.

### BRIEF DESCRIPTION OF THE DRAWINGS

Example embodiments will be described more fully hereinafter with reference to the accompanying drawings; however, the present invention may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a conceptual circuit diagram for describing an organic light emitting display device according to an exemplary embodiment of the present invention.

FIG. 2 is a cross-sectional view for describing one pixel of the display device illustrated in FIG. 1.

FIG. 3 is an enlarged view of region A of FIG. 2.

FIG. 4 is a top plan view corresponding to region A of FIG. 2.

FIG. 5 is a graph for describing hysteresis of a thin film transistor according to a temperature.

FIG. 6 is a cross-sectional view for describing one pixel of a display device according to another exemplary embodiment of the present invention.

FIG. 7 is an enlarged view of region B of FIG. 6.

FIG. 8 is a top plan view corresponding to region B of FIG. 6.

FIG. 9 is a cross-sectional view for describing one pixel of a display device according to yet another exemplary embodiment of the present invention.

FIG. 10 is an enlarged view of region C of FIG. 9.

FIG. 11 is a top plan view corresponding to region C of FIG. 9.

### DETAILED DESCRIPTION

Because embodiments of the present invention may be variously modified and have various forms, specific embodiments will be illustrated in the drawings and described in the detailed description. However it should be understood that the present invention is not limited to the specific embodiments, but includes all changes, equivalents, or alternatives which are included in the spirit and technical scope of the present invention.

In the description of respective drawings, similar reference numerals designate similar elements. In the accompanying drawings, sizes of structures are illustrated to be enlarged compared to actual sizes for clarity of embodiments of the present invention. Terms “first”, “second”, and the like may be used for describing various constituent elements, but the constituent elements should not be limited to the terms. The terms are used only to differentiate one constituent element from another constituent element. For example, a first element could be termed a second element, and similarly, a second element could be also termed a first element without departing from the scope of the present disclosure. Singular expressions used herein include plurals expressions unless they have definitely opposite meanings.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other specific characteristics, numbers, steps, operations, constituent elements, and components, or a combination thereof in advance. It will be understood that when an element such as a layer, film, region, or substrate is referred to as being “on” another element, it can be directly on the other element or intervening elements may also be present. On the contrary, it will be understood that when an element such as a layer, film, region, or substrate is referred to as being “beneath” another element, it can be directly beneath the other element or intervening elements may also be present.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another elementor layer, there are no intervening elements or layers present.

Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

Hereinafter, an exemplary embodiment of the present invention will be described in detail with reference to the accompanying drawings.

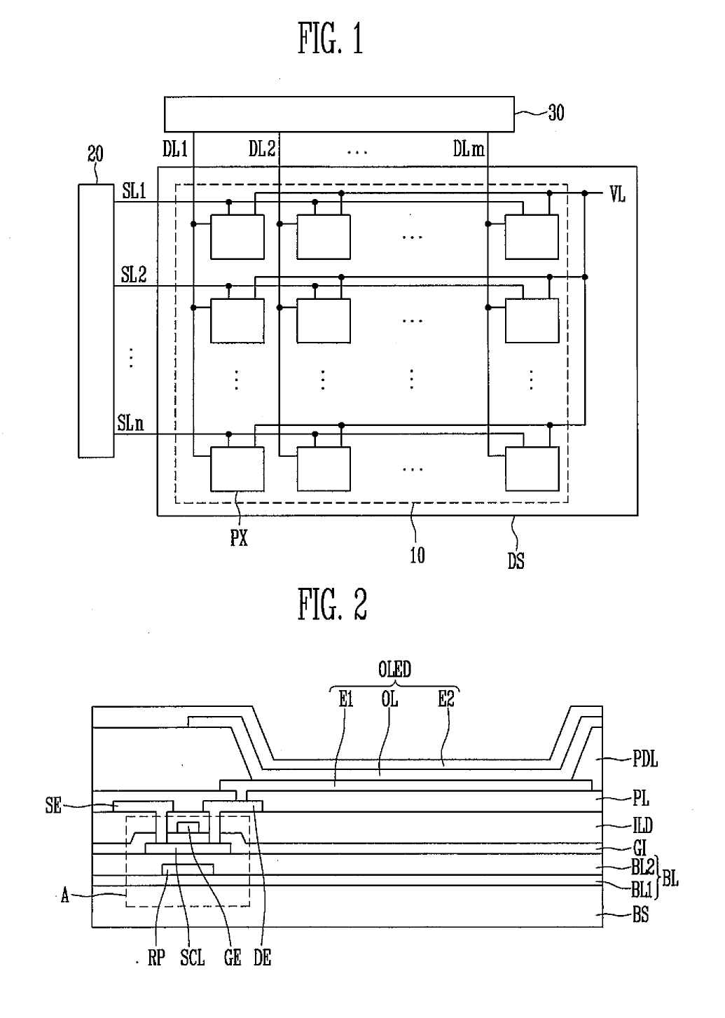

FIG. 1 is a conceptual circuit diagram for describing an organic light emitting display device according to an exemplary embodiment of the present invention.

Referring to FIG. 1, an organic light emitting display device according to an embodiment of the present invention may include a substrate DS including a display unit 10 for displaying an image, a scan drive 20, and a data drive 30.

The scan drive 20 and the data drive 30 are connected (e.g., coupled) to signal wires, respectively, to be electrically connected with the display unit 10. Here, the signal wire may include scan lines SL1, SL2, . . . , and SLn, data lines DL1, DL2, and DLm, and power supply lines VL, and at least one signal wire may cross other signal wires.

Particularly, the scan drive 20 may be electrically connected with the display unit by the plurality of scan lines SL1, SL2, . . . , and SLn. The scan drive 20 may transmit a scan signal to the display unit 10 through the scan lines SL1, SL2, . . . , and SLn. The scan lines SL1, SL2, . . . , and SLn may be extended in one direction on the substrate DS.

The data drive 30 may be electrically connected to the data lines DL1, DL2, . . . , and DLm. Accordingly, the data drive 30 may be electrically connected with the display unit 10 through the plurality of data lines DL1, DL2, . . . , and DLm. The data drive 30 may transmit a data signal to the display unit 10 through the data lines DL1, DL2, . . . , and DLm.

The data lines DL1, DL2, . . . , and DLm are extended in a different direction from that of SL1, SL2, . . . , and SLn to cross the scan lines SL1, SL2, . . . , and SLn. The data lines DL1, DL2, . . . , and DLm and the scan lines SL1, SL2, . . . , and SLn may cross each other.

The power supply lines VL may apply power to the display unit 10. The power supply lines VL may cross the data lines DL1, DL2, and DLm and the scan lines SL1, SL2, . . . , and SLn.

The display unit 10 may include a plurality of pixels PX. Each of the pixels PX may be electrically connected with a corresponding data line among the data line DL1, DL2, . . . , and DLm, a corresponding scan line among the scan lines SL1, SL2, and SLn, and a corresponding power supply line VL among the power supply lines VL.

The pixel PX may include at least one thin film transistor (not shown) disposed on the substrate DS, and a light emitting device (not shown) connected to the thin film transistor.

The thin film transistor may include the gate electrode (not shown), a semiconductor layer (not shown), a source electrode (not shown), and a drain electrode (not shown). Here, the gate electrode may be electrically connected with one of the scan lines SL1, SL2, . . . , and SLn. Further, the drain electrode may be electrically connected with one of the data line DL1, DL2, . . . , and DLm.

The light emitting device may be connected to the drain electrode of the thin film transistor. The light emitting device may include a first electrode (not shown) connected to the drain electrode, a second electrode (not shown) opposite to the first electrode, and an optical layer (not shown) disposed between the first electrode and the second electrode to allow light to pass through or generate light.

Further, the display device may be any one of a liquid crystal display device (LCD device), an electrophoretic display device (EPD device), an electrowetting display device (EWD device), and an organic light emitting display device (OLED device). In the present exemplary embodiment, for convenience of the description, the organic light emitting display device is described as an example of the display device. Accordingly, the optical layer may be an organic layer for generating light by using electrons and holes supplied from the first electrode and the second electrode.

At least one of the first electrode and the second electrode may allow light to pass through. For example, when the organic light emitting display device is a bottom emission display device, the first electrode may be a transmissive electrode, and the second electrode may be a reflective electrode. Further, when the organic light emitting display device is a top emission display device, the first electrode may be a reflective electrode, and the second electrode may be a transmissive electrode. Further, when the organic light emitting display device is a dual-side emission display device, both the first electrode and the second electrode may be transmissive electrodes. Further, one of the first electrode and the second electrode may be an anode electrode and the other one may be a cathode electrode. In order to improve light extraction efficiency, the light emitting device may use a semi-transmissive and reflective electrode as the transmissive electrode. Accordingly, light generated in the organic layer may be resonant between the first electrode and the second electrode, and light having wavelengths meeting an enforcement condition may be emitted to the outside of the display device.

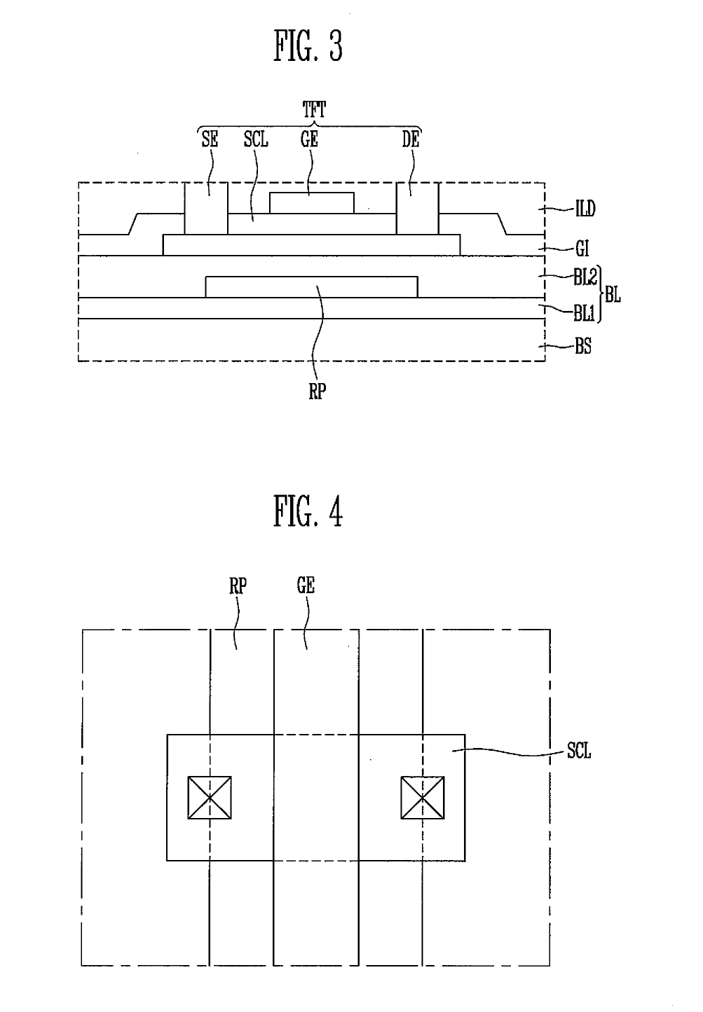

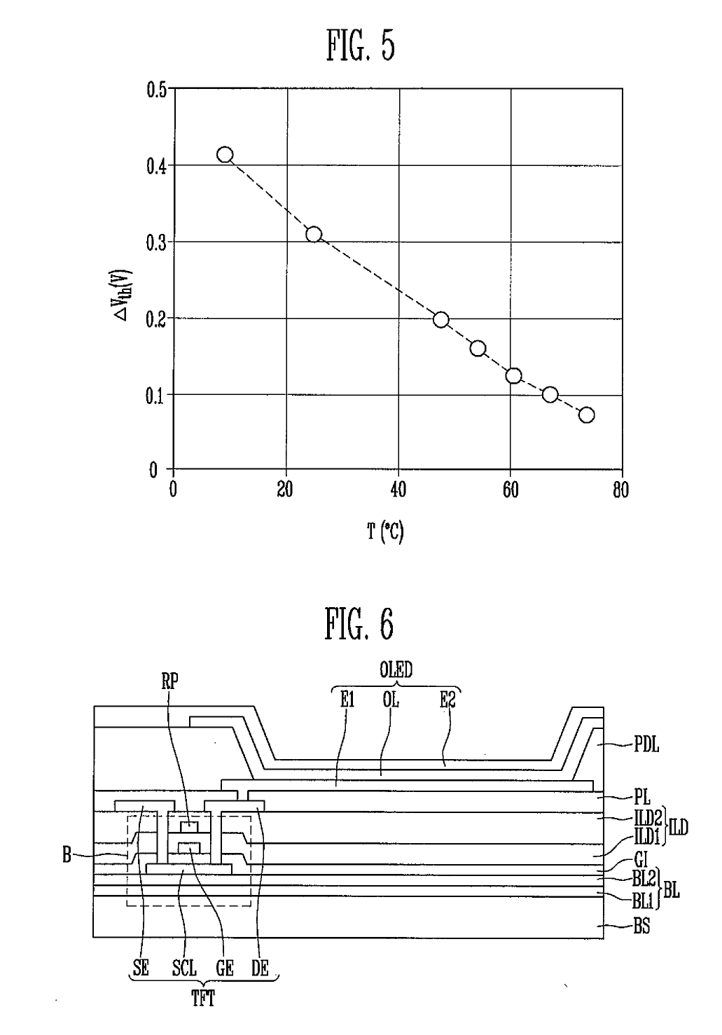

FIG. 2 is a cross-sectional view for describing one pixel of the display device illustrated in FIG. 1, FIG. 3 is an enlarged view of region A of FIG. 2, FIG. 4 is a top plan view corresponding to region A of FIG. 2, and FIG. 5 is a graph for describing hysteresis of a thin film transistor according to a temperature.

Referring to FIGS. 2 to 5, one pixel of the display device may include at least one thin film transistor TFT disposed on the base substrate BS, a temperature adjusting member RP for adjusting a temperature of the thin film transistor TFT, and an organic light emitting diode OLED connected to the thin film transistor TFT. Here, the temperature adjusting member RP may be included in the thin film transistor TFT.

The base substrate BS includes a transparent insulating material to allow light to pass through. Further, the base substrate BS may be a rigid type substrate or a flexible type substrate. The rigid type substrate may include a glass substrate, a quartz substrate, a glass ceramic substrate, or a crystalline glass substrate. The flexible type substrate may include a film substrate including a polymer organic material or a plastic substrate. The material included in the base substrate BS may have resistance (or heat resistance) to high processing temperature in a fabricating process.

The thin film transistor TFT may include a semiconductor layer SCL, a gate electrode GE, a source electrode SE, and a drain electrode DE.

The semiconductor layer SCL may be disposed on the base substrate BS. The semiconductor layer SCL may include at least one of amorphous silicon (a-Si), polycrystalline silicon (p-Si), and an oxide semiconductor. Here, the oxide semiconductor may include at least one among Zn, In, Ga, Sn, and a mixture thereof. For example, the oxide semiconductor may include an indium-gallium-zinc oxide (IGZO).

In the semiconductor layer SCL, regions connected with the source electrode SE and the drain electrode DE may be a source region and a drain region into which impurities are doped or injected. Further, in the semiconductor layer SCL, a region between the source region and the drain region may be a channel region.

Although not illustrated, when the semiconductor layer SCL includes an oxide semiconductor, a light blocking layer for blocking light incident on the oxide semiconductor layer SCL may be disposed on upper and lower parts of the oxide semiconductor layer SCL.

A gate insulating layer GI for covering the semiconductor layer SCL and insulating the semiconductor layer SCL and the gate electrode GE may be disposed on the semiconductor layer SCL and the base substrate BS. The gate insulating layer GI may include at least one of a silicon oxide (SiOx) and a silicon nitride (SiNx).

The gate electrode GE may be disposed so as to overlap the semiconductor layer SCL on the gate insulating layer GI. Further, the gate electrode GE may include at least one of aluminum AL, an aluminum alloy (Al-alloy), silver (Ag), tungsten (W), cooper (Cu), nickel (Ni), chrome (Cr), molybdenum (Mo), titanium (Ti), platinum (Pt), tantalum (Ta), neodymium (Nd), scandium (Sc), and an alloy thereof.

An interlayer insulating layer ILD may be disposed on the gate insulating layer GI and the gate electrode GE. The interlayer insulating layer ILD may include at least one of a silicon oxide and a silicon nitride similar to the gate insulating layer GI. Further, the interlayer insulating layer ILD may expose a part of the source region and the drain region of the semiconductor layer SCL.

The source electrode SE and the drain electrode DE may be disposed on the interlayer insulating layer ILD. The source electrode SE and the drain electrode DE may include at least one of copper (Cu), a copper alloy (Cu-alloy), aluminum (Al), and an aluminum alloy (Al-alloy).

Further, the source electrode SE and the drain electrode DE may be insulated from the gate electrode GE by the interlayer insulating layer ILD. Further, the source electrode SE and the drain electrode DE are respectively connected with the source region and the drain region of the semiconductor layer SCL.

In the present exemplary embodiment, a case where the thin film transistor TFT is a thin film transistor having a top gate structure has been described as an example, but the thin film transistor is not limited thereto. For example, the thin film transistor TFT may be a thin film transistor having a bottom gate structure.

A buffer layer BL may be disposed between the base substrate BS and the thin film transistor TFT. The buffer layer BL may include at least one of a silicon oxide and a silicon nitride. For example, the buffer layer BL may include a first buffer layer BL1 and a second buffer layer BL2. The first buffer layer BL1 may be disposed on the base substrate BS, and include the silicon nitride. The second buffer layer BL2 may be disposed on the first buffer layer BL1, and include the silicon oxide.

The buffer layer BL may prevent or substantially prevent the impurities included in the base substrate BS from being diffused to the thin film transistor TFT and the organic light emitting diode. Further, the buffer layer BL prevents or substantially prevents external moisture and oxygen from permeating into the thin film transistor TFT and the organic light emitting diode. Further, the buffer layer BL may planarize a surface of the base substrate BS.

The temperature adjusting member RP overlapping the semiconductor layer SCL may be disposed between the first buffer layer BL1 and the second buffer layer BL2. That is, the second buffer layer BL2 may cover the temperature adjusting member RP. Accordingly, the temperature adjusting member RP may be insulated from the thin film transistor TFT by the second buffer layer BL2.

The temperature adjusting member RP is a type of resistor, and when power is applied to the temperature adjusting member RP, the temperature adjusting member RP may generate heat. Accordingly, the temperature adjusting member RP may adjust a temperature of the thin film transistor by heating the thin film transistor. For example, the temperature adjusting member RP may include amorphous silicon (a-Si), polycrystalline silicon (p-Si), and a metal material. Here, the metal material may include at least one of aluminum (Al), an aluminum alloy (Al-alloy), titanium (Ti), and a titanium alloy (Ti-alloy).

A width in a direction perpendicular to a current flow in the temperature adjusting member RP may be larger than a length of the channel region of the thin film transistor TFT.

A passivation layer PL may be disposed on the base substrate BS on which the thin film transistor TFT is disposed. That is, the passivation layer PL may cover the thin film transistor TFT. Further, the passivation layer PL may include a contact hole CL through which a part of the drain electrode DE is exposed.

The passivation layer PL may include at least one layer. For example, the passivation layer PL may include an inorganic passivation layer, and an organic passivation layer disposed on the inorganic passivation layer. The inorganic passivation layer may include at least one of a silicon oxide and a silicon nitride. Further, the organic passivation layer may include at least one of acryl, polyimide (PI), polyamide (PA), and benzocyclobutene (BCB). That is, the organic passivation layer may be a planarizing layer, which is transparent and flexible to smooth and planarize a curve of a lower structure.

The organic light emitting diode connected to the drain electrode DE may be disposed on the passivation layer PL. The organic light emitting diode may include a first electrode E1 connected with the drain electrode DE, an organic layer OL disposed on the first electrode E1, and a second electrode E2 disposed on the organic layer OL.

In the present exemplary embodiment, a case where the first electrode E1 is a transmissive anode electrode and the second electrode E2 is a reflective cathode electrode is described as an example.

The first electrode E1 may be disposed on the passivation layer PL. The first electrode E1 may include a transparent conductive oxide having a higher work function than that of the second electrode E2. For example, the first electrode E1 may include at least one of an indium tin oxide (ITO), an indium zinc oxide (IZO), an aluminum zinc oxide (AZO), a gallium doped zinc oxide (GZO), a zinc tin oxide (ZTO), a Gallium tin oxide (GTO), and a fluorine doped tin oxide (FTO).

Most of the regions of the first electrode E1 may be exposed by a pixel defining layer PLD. The pixel defining layer PDL may include an organic insulating material. For example, the pixel defining layer PDL may include at least one of polystylene, polymethylmetaacrylate (PMMA), polyacrylonitrile (PAN), polyamide, polyimide, polyarylether, heterocyclic polymer, parylene, fluorinated polymer, epoxy resin, benzocyclobutene series resin, siloxane series resin, and silane resin.

The organic layer OL is disposed on all or a portion of the first electrode E1 which is exposed by the pixel defining layer PDL. The organic layer OL may include at least an emitting layer EML, and may generally have a multilayer thin film structure. For example, the organic layer OL may include: a hole injection layer HIL for injecting holes; a hole transport layer HTL having an excellent hole transporting property, and for suppressing a movement of an electron, which fails to be combined in the emitting layer EML, to increase an opportunity for the holes and the electrons to be re-combined; the emitting layer EML for emitting light through the re-combination of the injected electrons and holes; a hole blocking layer HBL for suppressing a movement of holes which fail to be combined in the emitting layer EML; an electron transport layer ETL for smoothly transporting electrons to the emitting layer EML; and an electron injection layer (EIL) for injecting electrons. A color of light generated in the emitting layer of the organic layer OL may be any one of red, green, blue, and white, but is not limited thereto. For example, a color of light generated in the emitting layer of the organic layer OL may be any one of magenta, cyan, and yellow.

The second electrode E2 may be disposed on the organic layer OL, and include a material having a smaller work function than that of the first electrode E1, and excellent reflectivity. For example, the second electrode E2 may include at least one of silver (Ag), aluminum (Al), platinum (Pt), gold (Au), nickel (Ni), chrome (Cr), calcium (Ca), and an alloy thereof.

Although not illustrated in the drawing, a conductive layer may be disposed on the second electrode E2 in order to prevent or reduce a voltage drop (IR-drop) of the second electrode E2. The conductive layer may include the same or substantially the same material as that of the first electrode E1.

In the aforementioned display device, when a signal is applied to the temperature adjusting member RP, the temperature adjusting member RP generates heat, and heats the thin film transistor TFT. For example, the heat generated by the temperature adjusting member RP heats the channel region of the semiconductor layer SCL. When the channel region is heated, hysteresis of the thin film transistor TFT is reduced.

The signal applied to the temperature adjusting member RP may be applied while overlapping a scan signal applied to the gate electrode GE. For example, the signal applied to the temperature adjusting member RP may be applied to the temperature adjusting member RP before the scan signal is applied. Further, when the scan signal is ended, the signal applied to the temperature adjusting member RP may be ended. In addition, a voltage of the signal applied to the temperature adjusting member RP may be higher than a voltage of the scan signal.

As illustrated in FIG. 5, it can be seen that when a temperature of the channel region increases, the hysteresis of the thin film transistor TFT decreases. Accordingly, it can be seen that when the channel region of the thin film transistor TFT is heated (e.g., heated to a predetermined temperature) by applying power to the temperature adjusting member RP, operation reliability of the thin film transistor TF improves.

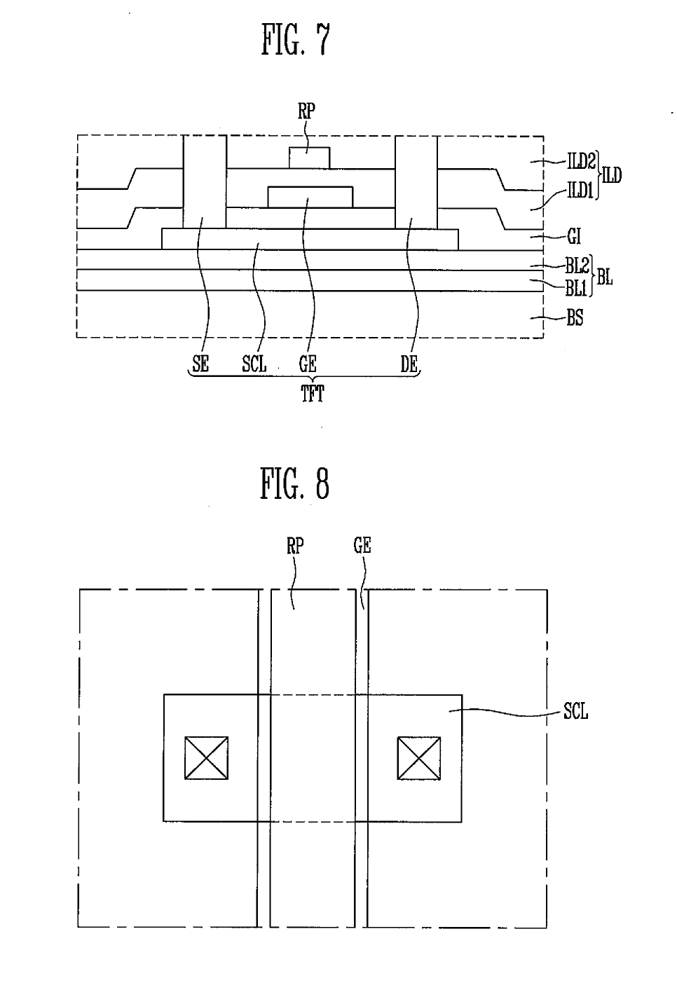

Hereinafter, other exemplary embodiments of the present invention will be described with reference to FIGS. 6 to 11. In FIGS. 6 to 11, the same or substantially the same constituent elements as those illustrated in FIGS. 1 to 5 are denoted by the same reference numerals, and detailed descriptions thereof will be omitted. Further, in order to avoid overlapping descriptions in FIGS. 6 and 11, differences from FIGS. 1 to 5 will be primarily described below.

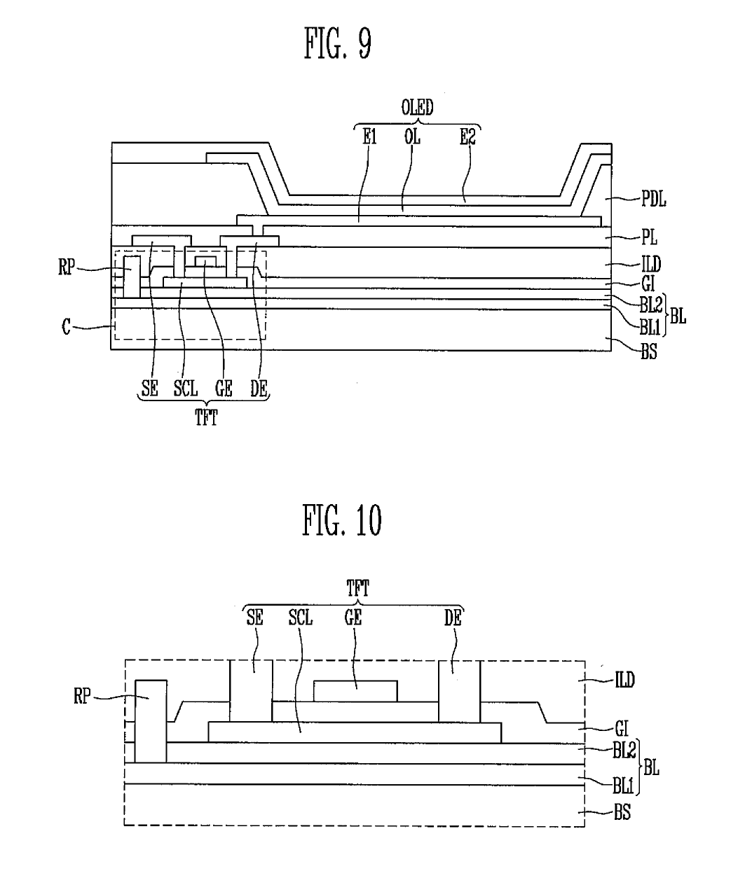

FIG. 6 is a cross-sectional view for describing one pixel of a display device according to another exemplary embodiment of the present invention, FIG. 7 is an enlarged view of region B of FIG. 6, and FIG. 8 is a top plan view corresponding to region B of FIG. 6.

Referring to FIGS. 6 to 8, one pixel of the display device may include at least one thin film transistor disposed on a base substrate, a temperature adjusting member RP for adjusting a temperature of the thin film transistor TFT, and a organic light emitting diode connected to the thin film transistor TFT.

The thin film transistor TFT may include a semiconductor layer SCL disposed on the base substrate BS, a gate electrode GE insulated from the semiconductor layer SCL by a gate insulating layer GI, and a source electrode SE and a drain electrode DE, which are connected to opposite ends of the semiconductor layer SCL and insulated from the gate electrode GE by an interlayer insulating layer ILD.

The interlayer insulating layer ILD may include a first interlayer insulating layer ILD1 and a second interlayer insulating layer ILD2. The interlayer insulating layer ILD may expose a part of the source region and the drain region of the semiconductor layer SCL.

The first interlayer insulating layer ILD1 may be disposed on the gate insulating layer GI and the gate electrode GE, and cover the gate electrode GE. The first interlayer insulating layer ILD1 may include at least one of a silicon oxide and a silicon nitride.

The second interlayer insulating layer ILD2 may include the first interlayer insulating layer ILD1. Further, the second interlayer insulating layer ILD2 may include the same or substantially the same material as that of the first interlayer insulating layer ILD1.

The temperature adjusting member RP overlapping the gate electrode GE may be disposed between the first interlayer insulating layer ILD1 and the second interlayer insulating layer ILD2. Accordingly, the temperature adjusting member RP may be insulated from the thin film transistor TFT.

The temperature adjusting member RP may include amorphous silicon (a-Si), polycrystalline silicon (p-Si), and a metal material. Here, the metal material may include at least one of aluminum (Al), an aluminum alloy (Al-alloy), titanium (Ti), and a titanium alloy (Ti-alloy). Further, a width of the temperature adjusting member RP in a direction perpendicular to a current flow may be smaller than a width of the gate electrode GE.

The organic light emitting diode may include a first electrode E1 connected with the drain electrode DE, an organic layer OL disposed on the first electrode E1, and a second electrode E2 disposed on the organic layer OL.

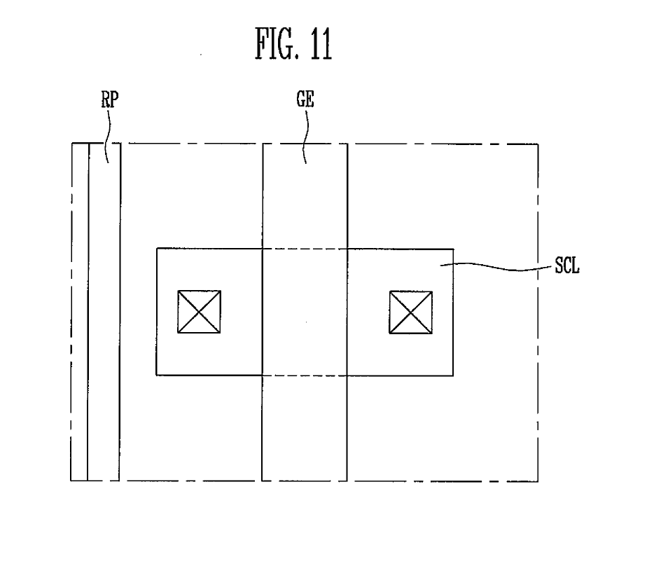

FIG. 9 is a cross-sectional view for describing one pixel of a display device according to yet another exemplary embodiment of the present invention, FIG. 10 is an enlarged view of region C of FIG. 9, and FIG. 11 is a top plan view corresponding to region C of FIG. 9.

Referring to FIGS. 9 to 11, one pixel of the display device may include at least one thin film transistor disposed on a base substrate, a temperature adjusting member RP for adjusting a temperature of the thin film transistor TFT, and an organic light emitting diode connected to the thin film transistor TFT.

The thin film transistor TFT may include a semiconductor layer SCL disposed on the base substrate BS, a gate electrode GE insulated from the semiconductor layer SCL by a gate insulating layer GI, and a source electrode SE and a drain electrode DE, which are connected to both ends of the semiconductor layer SCL and insulated from the gate electrode GE by an interlayer insulating layer ILD.

The temperature adjusting member RP may be insulated from the thin film transistor, and disposed to be spaced apart from the thin film transistor TFT at one side of the thin film transistor TFT. For example, the temperature adjusting member RP may be disposed to be spaced apart from the source electrode SE at one side of the source electrode SE. The temperature adjusting member RP may include amorphous silicon (a-Si), polycrystalline silicon (p-Si), and a metal material. Here, the metal material may include at least one of aluminum (Al), an aluminum alloy (Al-alloy), titanium (Ti), and a titanium alloy (Ti-alloy).

The organic light emitting diode may include a first electrode E1 connected with the drain electrode DE, an organic layer OL disposed on the first electrode E1, and a second electrode E2 disposed on the organic layer OL.

By way of summation and review, the aforementioned thin film transistor includes the temperature adjusting member, thereby reducing hysteresis. Therefore, it is possible to improve reliability of the thin film transistor. Further, the hysteresis of the thin film transistor is reduced, thereby improving a display quality of the display device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims, and their equivalents.

What is claimed is:

1. A thin film transistor comprising:
a semiconductor layer on a base substrate and having a source region, a drain region, and a channel region;
a gate insulating layer covering the semiconductor layer;
a gate electrode on the gate insulating layer and overlapping the channel region;
an interlayer insulating layer covering the gate electrode;
a source electrode and a drain electrode on the interlayer insulating layer and respectively coupled to the source region and the drain region; and
a temperature adjusting member configured to adjust a temperature of the channel region by heating the channel region.

2. The thin film transistor of claim 1, further comprising:
a buffer layer between the base substrate and the semiconductor layer,
wherein the buffer layer comprises:
a first buffer layer on the base substrate; and
a second buffer layer on the first buffer layer.

3. The thin film transistor of claim 2, wherein the temperature adjusting member is between the first buffer layer and the second buffer layer, and overlaps the semiconductor layer.

4. The thin film transistor of claim 3, wherein a width of the temperature adjusting member in a direction perpendicular to a current flow of the temperature adjusting member is larger than a length of the channel region.

5. The thin film transistor of claim 1, wherein the interlayer insulating layer comprises:
a first interlayer insulating layer configured to cover the gate electrode; and
a second interlayer insulating layer on the first interlayer insulating layer,
wherein the temperature adjusting member is between the first interlayer insulating layer and the second interlayer insulating layer and overlaps the gate electrode.

6. The thin film transistor of claim 5, wherein a width of the temperature adjusting member in a direction perpendicular to a current flow of the temperature adjusting member is smaller than a width of the gate electrode.

7. The thin film transistor of claim 1, wherein the temperature adjusting member is spaced apart from the source electrode at a side of the source electrode.

8. The thin film transistor of claim 1, wherein the temperature adjusting member comprises at least one of amorphous silicon, polycrystalline silicon, aluminum, an aluminum alloy, titanium, and a titanium alloy.

9. A display device comprising:
a base substrate;
a thin film transistor on the base substrate;
a light emitting device coupled with the thin film transistor; and
a temperature adjusting member insulated from the thin film transistor and configured to adjust a temperature of the thin film transistor by heating the thin film transistor.

10. The display device of claim 9, wherein the thin film transistor comprises:
a semiconductor layer on the base substrate and having a source region, a drain region, and a channel region;
a gate insulating layer covering the semiconductor layer;
a gate electrode on the gate insulating layer and overlapping the channel region;
an interlayer insulating layer covering the gate electrode; and
a source electrode and a drain electrode on the interlayer insulating layer and respectively coupled to the source region and the drain region.

11. The display device of claim 10, further comprising:
a buffer layer between the base substrate and the thin film transistor,
wherein the buffer layer comprises:
a first buffer layer on the base substrate; and
a second buffer layer on the first buffer layer.

12. The display device of claim 11, wherein the temperature adjusting member is between the first buffer layer and the second buffer layer, and overlaps the semiconductor layer.

13. The display device of claim 12, wherein a width of the temperature adjusting member in a direction perpendicular to a current flow of the temperature adjusting member is larger than a length of the channel region.

14. The display device of claim 10, wherein the interlayer insulating layer comprises:
a first interlayer insulating layer covering the gate electrode; and
a second interlayer insulating layer on the first interlayer insulating layer, wherein the temperature adjusting member is between the first interlayer insulating layer and the second interlayer insulating layer, and overlaps the gate electrode.

15. The display device of claim 14, wherein a width of the temperature adjusting member in a direction perpendicular to a current flow of the temperature adjusting member is smaller than a width of the gate electrode.

16. The display device of claim 9, wherein the temperature adjusting member is spaced apart from the thin film transistor at a side of the thin film transistor.

17. The display device of claim 9, wherein the temperature adjusting member comprises at least one of amorphous silicon, polycrystalline silicon, aluminum, an aluminum alloy, titanium, and a titanium alloy.
